(19) United States
(12) Patent Application Publication
(10) Pub. No.: US 2026/0253821 A1
(43) Pub. Date: Aug. 27, 2026

(54) Rotary Switch for Vehicle

(71) Applicant: Jet Optoelectronics Co., Ltd., Taipei City (TW)

(72) Inventors: Wei-Kuo Chiu, Taipei City (TW); Chin-Chang Liu, Taipei City (TW); Bo-Shen Huang, Taipei City (TW)

(21) Appl. No.: 19/326,397

(22) Filed: Sep. 11, 2025

(30) Foreign Application Priority Data
Feb. 26, 2025 (CN) 202510216475.2

(51) Int. Cl. H01H 19/14; H05K 7/14

(52) U.S. Cl. CPC H01H 19/14; H05K 7/1427

(57) ABSTRACT

The present disclosure provides a rotary switch for vehicle, which includes a bearing frame, a circuit board module and a pressing sleeve. The bearing frame has a cylindrical structure, and the bearing frame is provided with an accommodation space and a plurality of elastic pressing units spaced apart along an axial direction of the bearing frame. The circuit board module is disposed in the accommodation space; the circuit board module is provided with a plurality of push switches spaced apart corresponding to the plurality of elastic pressing units. The pressing sleeve is rotatably mounted on the bearing frame; the pressing sleeve is provided with a plurality of pressing protrusions corresponding to the plurality of elastic pressing units, and the plurality of pressing protrusions are arranged in a stepped manner along a circumferential direction of the bearing frame. Wherein, a pressing column of the elastic pressing units has an arc-shaped structure with one end facing the pressing switch being convex toward the pressing switch. The rotary switch for vehicle of the present disclosure can ensure the stability and accuracy of pressing by means of the above configuration.

### CROSS-REFERENCE TO RELATED APPLICATION

This application claims the benefit of Chinese Patent Application No. 202510216475.2, filed on Feb. 26, 2025, in the National Intellectual Property Administration of the People's Republic of China, the disclosure of which is incorporated herein in its entirety by reference.

### BACKGROUND OF THE INVENTION

### 1. Field of the Invention

The present disclosure relates to the technical field of switches, and in particular to a multi-stage rotary switch for vehicle.

### 2. Description of the Related Art

The wiper control system on general vehicles is a multi-stage control system. Therefore, the user can adjust the oscillation frequency of the wipers of the front windshield or rear windshield according to the intensity of rain by toggling or rotating the wiper switch so that the oscillation frequency of the wipers can appropriately correspond to the current rain intensity.

Referring to FIG. 1, the current mechanism of the rotary switch of the wiper lever mostly adopts a cylindrical circuit board bracket 11 and a push switch 13 on a hard electronic circuit board 12. The triggering method is that when the sleeve 14 is rotated, the internal step structure pushes the circular structure column 15 and triggers the push switch 13. When the rotary switch sleeve 14 rotates and touches the circular structure column 15, the inclined surface drives the circular structure column 15 to move up/down to trigger the push switch 13, but since the circular structure column 15 and the cylindrical circuit board bracket 11 are in surface contact, failure/malfunction often occur due to uneven force on the contact surface or large friction.

In summary, the inventor of the present disclosure has considered and designed a rotary switch for vehicle in order to improve the deficiencies of the prior art and further promote its industrial implementation and utilization.

### SUMMARY OF THE INVENTION

The primary objective of the present disclosure is to provide a rotary switch for vehicle to solve the above-mentioned problem.

To achieve the foregoing objective, the present disclosure provides a rotary switch for vehicle, which includes a bearing frame, a circuit board module and a pressing sleeve. The bearing frame has a cylindrical structure, and the bearing frame is provided with an accommodation space and a plurality of elastic pressing units spaced apart along an axial direction of the bearing frame. The circuit board module is disposed in the accommodation space; the circuit board module is provided with a plurality of push switches spaced apart corresponding to the plurality of elastic pressing units. The pressing sleeve is rotatably mounted on the bearing frame; the pressing sleeve is provided with a plurality of pressing protrusions corresponding to the plurality of elastic pressing units, and the plurality of pressing protrusions are arranged in a stepped manner along a circumferential direction of the bearing frame. Wherein, a pressing column of the elastic pressing units has an arc-shaped structure with one end facing the pressing switch being convex toward the pressing switch.

Preferably, the elastic pressing unit includes a plurality of first elastic pressing units; the first elastic pressing unit is integrally formed to include a U-shaped portion, a bearing portion, a pushing protrusion and the pressing column; one end of the U-shaped portion is integrally connected to the bearing frame, and the other end of the U-shaped portion is connected to the bearing portion; the pushing protrusion is arranged on one side of the bearing portion corresponding to the pressing protrusion; the pressing column is arranged on the other side of the bearing portion and opposite to the pushing protrusion.

Preferably, the elastic pressing unit includes at least one second elastic pressing unit; the second elastic pressing unit is integrally formed to include a cross bar, a C-shaped portion, the bearing portion, the pushing protrusion and the pressing column; both ends of the cross bar are integrally connected to the bearing frame; one end of the C-shaped portion is connected to the cross bar, and the other end of the C-shaped portion is connected to the bearing portion; the pushing protrusion is arranged on one side of the bearing portion corresponding to the pressing protrusion; the pressing column is arranged on the other side of the bearing portion and opposite to the pushing protrusion.

Preferably, the second elastic pressing unit is adjacent to one end of the accommodation space and is located away from a rotating member of the rotary switch for vehicle.

Preferably, the rotary switch for vehicle includes a rotating member; the rotating member is located at one end of the bearing frame and fixed to the pressing sleeve.

Preferably, the bearing frame includes at least one elastic positioning portion; the elastic positioning portion is located at one end of the bearing frame and is adjacent to the rotating member; the rotating member includes a wave portion corresponding to the elastic positioning portion; the elastic positioning portion is embedded in one of the troughs of the wave portion.

Preferably, the distance between the troughs of the wave portion corresponds to the distance between the plurality of elastic pressing units.

Preferably, the rotary switch for vehicle includes an outer sleeve; the outer sleeve is sleeved on the outside of the pressing sleeve.

Preferably, two of the first elastic pressing units form a group, and a reinforcing rib is provided between two of the first elastic pressing units in a group.

The technical features of the present disclosure will be described in detail below with specific embodiments and accompanying drawings so that those skilled in the art can easily understand the objectives, technical features, and advantages of the present disclosure.

### BRIEF DESCRIPTION OF THE DRAWINGS

In order to clearly illustrate the technical solutions of the embodiments of the present disclosure, the accompanying drawings used in describing the embodiments of the present disclosure will be briefly introduced below. Obviously, the accompanying drawings described below are only some embodiments of the present disclosure. For those skilled in the technical field to which the present disclosure belongs, other accompanying drawings can also be obtained based on these accompanying drawings.

FIG. 1 is a schematic structural diagram of a conventional rotary switch for vehicle.

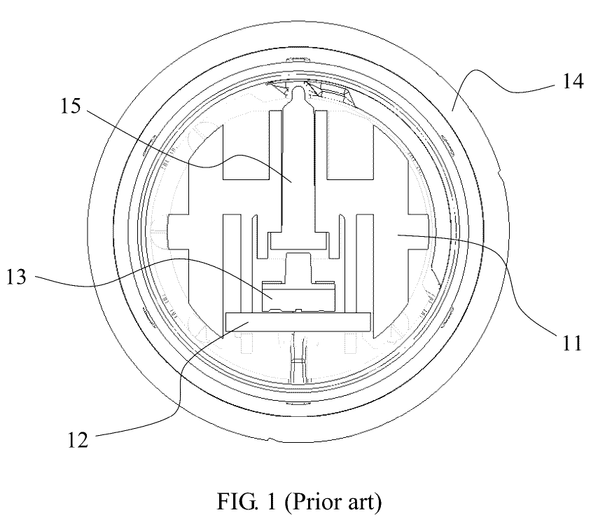

FIG. 2 is an exploded schematic diagram of the rotary switch for vehicle according to the present disclosure.

FIG. 3 is a schematic diagram illustrating the assembly of the rotary switch for vehicle according to the present disclosure.

FIG. 4 is a cross-sectional schematic diagram of the rotary switch for vehicle according to the present disclosure.

FIG. 5 is a structural schematic diagram of a pressing sleeve of a rotary switch for vehicle according to the present disclosure.

FIG. 6 is a structural schematic diagram of a rotary member of a rotary switch for vehicle according to the present disclosure.

### DETAILED DESCRIPTION OF THE PREFERRED EMBODIMENTS

The advantages, features and technical methods achieved by the present disclosure will be described in more detail with reference to exemplary embodiments and the accompanying drawings so as to be easier to understand. The present disclosure may be implemented in different forms and should not be understood as being limited to the embodiments described herein. On the contrary, for those skilled in the art, the provided embodiments will make the disclosure of the present disclosure more thorough and comprehensive and fully convey the scope of the present disclosure.

It should be understood that when used in the present specification and the appended claims, the term “comprising” indicates the presence of the described features, integrals, steps, operations, elements and/or components, but does not exclude the presence or addition of one or more other features, integrals, steps, operations, elements, components and/or collections thereof. The term “and/or” used in the present specification and the appended claims refers to any combination of one or more of the associated listed items and all possible combinations, and includes those combinations.

It should be understood that although the terms “first”, “second”, etc. may be used in the present disclosure to describe various components, parts, regions, sections, layers and/or parts, these components, parts, regions, sections, layers and/or parts should not be limited by these terms. These terms are only used to distinguish one component, part, region, section, layer and/or part from another component, part, region, section, layer and/or part.

Unless otherwise defined, all terms (including technical and scientific terms) used herein have the same meaning as commonly understood by one of ordinary skill in the art to which the present disclosure belongs. It will be further understood that terms such as those defined in commonly used dictionaries should be interpreted as having definitions consistent with their meanings in the context of the relevant technology and the present disclosure, and will not be interpreted as idealized or overly formal meanings unless explicitly defined in this article.

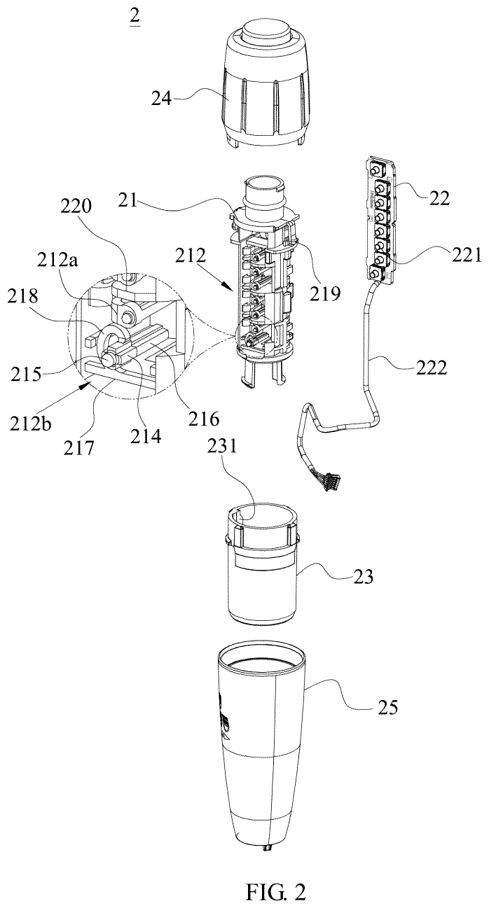

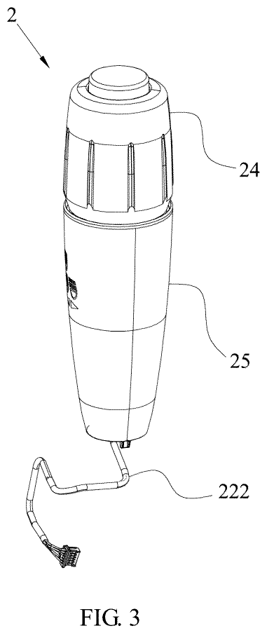

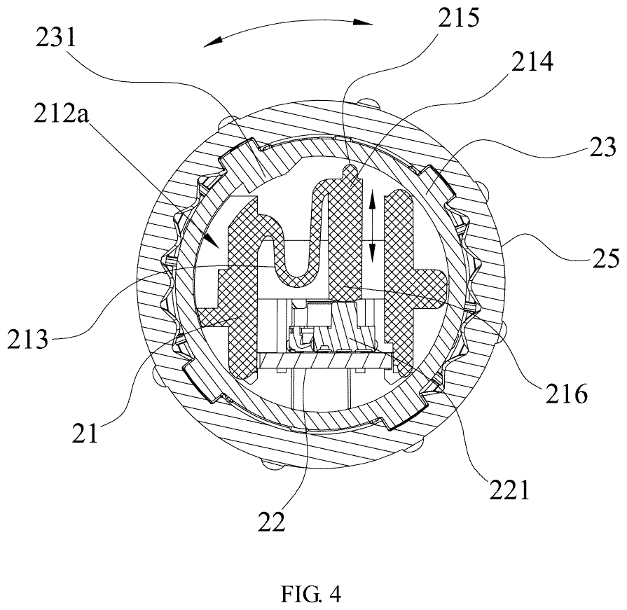

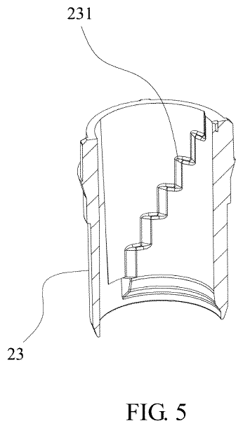

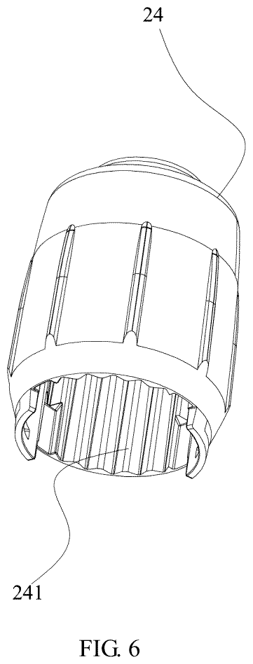

Please refer to FIGS. 2 to 6. FIGS. 2 to 4 are respectively the exploded schematic diagram, the assembled schematic diagram and the cross-sectional schematic diagram according to the rotary switch for vehicle of the present disclosure. FIG. 5 is a structural schematic diagram of a pressing sleeve of a rotary switch for vehicle according to the present disclosure. FIG. 6 is a structural schematic diagram of a rotary member of a rotary switch for vehicle according to the present disclosure. The rotary switch for vehicle of the present disclosure is mainly used in a wiper control system, and can also be used in other automotive control systems or control modules of other electronic devices other than automotive in different application modes. The rotary switch for vehicle 2 of the present disclosure includes a bearing frame 21, a circuit board module 22 and a pressing sleeve 23.

The bearing frame 21 may be made of plastic material and is made by injection molding and other processes. The bearing frame 21 has an accommodation space 211 and a plurality of elastic pressing units 212 spaced apart along the axial direction of the bearing frame 21.

The circuit board module 22 may be a rigid printed circuit board. The circuit board module 22 is disposed in the accommodation space 211; the circuit board module 22 is provided with a plurality of press switches 221 spaced apart corresponding to the plurality of elastic pressing units 212. The circuit board module 22 may be fixed in the accommodation space 211 by means of adhesive layer, structural fixing, hot melting, welding, etc. In addition, the circuit board module 22 is provided with a circuit related to the control of the press switches 221, which is a technical means well known or commonly used by those skilled in the art, and therefore will not be described in detail herein.

The pressing sleeve 23 may be a cylindrical structure made of plastic material with openings at both ends. The pressing sleeve 23 and the bearing frame 21 may be rotatably sleeved on the bearing frame 21; the inner circumferential surface of the pressing sleeve 23 is provided with a plurality of pressing protrusions 231 corresponding to the plurality of elastic pressing units 212, and the plurality of pressing protrusions 231 are arranged in a stepped manner along the circumferential direction of the bearing frame.

It is worth noting that the pressing column 216 of the elastic pressing unit 212 has an arc-shaped structure at one end facing the pressing switch 221 and convex toward the pressing switch 221.

Specifically, the elastic pressing unit 212 includes a plurality of first elastic pressing units 212a and at least one second elastic pressing unit 212b.

The first elastic pressing unit 212a is integrally formed to include a U-shaped portion 213, a bearing portion 214, a pushing protrusion 215 and the pressing column 216; one end of the U-shaped portion 213 is integrally connected to the bearing frame 21, and the other end of the U-shaped portion 213 is connected to the bearing portion 214; the pushing protrusion 215 of the first elastic pressing unit 212a is arranged on one side of the bearing portion 214 corresponding to the pressing protrusion 231; the pressing column 216 of the first elastic pressing unit 212 a is arranged on the other side of the bearing portion 214, and opposite to the pushing protrusion 215.

The second elastic pressing unit 212b is integrally formed to include a crossbar 217, a C-shaped portion 218, the bearing portion 214, the pushing protrusion 215 and the pressing column 216. Both ends of the crossbar 217 are integrally connected to the bearing frame 21; one end of the C-shaped portion 218 is connected to the crossbar 217, and the other end of the C-shaped portion 218 is connected to the bearing portion 214 of the second elastic pressing unit 212b. The pushing protrusion 215 of the second elastic pressing unit 212b is arranged on one side of the bearing portion 214 of the second elastic pressing unit 212b corresponding to the pressing protrusion 231; the pressing column 216 of the second elastic pressing unit 212 b is arranged on the other side of the bearing portion 214 and opposite to the pushing protrusion 215.

Thus, when the pressing sleeve 23 is rotated by force, the pressing protrusion 231 corresponding to the inner circumference of the pressing sleeve 23 will press against the pushing protrusion 215, so that the pressing column 216 moves toward the pressing switch 221, and one end of the pressing switch 221 with an arc-shaped structure may trigger the pressing switch 221.

In addition, two first elastic pressing units 212a form a group, and a reinforcing rib 220 is provided between the two first elastic pressing units 212a in a group, thereby increasing the structural strength of the bearing frame 21.

It is worth noting that the rotary switch for vehicle 2 includes the rotating member 24; the rotating member 24 is located at one end of the bearing frame 21 and fixed to the pressing sleeve 23. Regarding the fixing method of the rotating member 24, for example, at least two buckle parts may be provided on the pressing sleeve 23, and two buckling parts corresponding to the buckle parts may be provided on the rotating member 24, so that the rotating member 24 may be fixed to the pressing sleeve 23 by the buckle parts and the buckling parts.

Specifically, the bearing frame 21 includes at least one elastic positioning portion 219; the elastic positioning portion 219 is located at one end of the bearing frame 21 and is adjacent to the rotating member 24. The rotating member 24 includes a wave portion 241 corresponding to the elastic positioning portion 219; the elastic positioning portion 219 is embedded in one of the valleys of the wave portion 241. Preferably, the spacing between each elastic pressing unit 212 may be the same, and the distance between the troughs of the wave portion 241 corresponds to the distance between multiple elastic pressing units 212; that is, the distance between the troughs of the wave portion 241 corresponds to the distance between the plurality of press switches 221. The configuration of the wave portion 241 and the elastic positioning portion 219 can provide the user with a hand feeling when rotating the rotating member 23 to drive the bearing frame 21 and to switch between different stages, so that the user can clearly know the switching points of different stages. For example, when the rotary switch for vehicle 2 of the present disclosure is applied to or arranged on a wiper lever, the wiper may be controlled to have different swing frequencies by rotating the rotating member 24.

Incidentally, the second elastic pressing unit 212b is adjacent to one end of the accommodation space 211 and is located away from the rotating member 24 of the rotary switch for vehicle 2. In addition, the circuit board module 22 may be provided with a connecting wire 222 at one end adjacent to the second elastic pressing unit 212b, and the connecting wire 222 passes through the outside of the bearing frame 21, so as to be (directly or indirectly) electrically connected to a control module or control system in the mobile vehicle, such as a Controller Area Network (CAN or CAN bus).

Preferably, the rotary switch for vehicle includes an outer sleeve 25. The outer sleeve 25 may be made of plastic materials and is sleeved on the outside of the pressing sleeve 23. The outer sleeve 25 may be provided with a connecting structure at one end opposite to the sleeve of the pressing sleeve 23, and the connecting structure is configured to be connected or fixed to, for example, a wiper lever of a wiper control system or form a part of the wiper lever, and the connecting wire 222 is then electrically connected to a controller area network (CAN bus) via the wiper lever.

In summary, the rotary switch for vehicle of the present disclosure may reduce the failure/malfunction problem of switches caused by the combination of parts through the elastic pressing unit designed with cantilever parts. The elastic pressing unit simplifies the combination of the circuit board bearing frame and the circular structure column in the prior art, which is not only convenient for assembly but also reduces costs. In addition, the elastic pressing unit replaces the shaft and hole matching design of the circular structure column in the configuration, therefore reduces the surface friction when the circuit board bearing frame is combined with the circular structure column, and avoids the problem that the surface friction may affect the trigger switch, thereby ensuring the stability and accuracy of the pressing.

References to “one embodiment” or “some embodiments” etc. described herein means that one or more embodiments of the present disclosure include specific features, structures or characteristics described in conjunction with the embodiment. Thus, the statements of “in one embodiment”, “in some embodiments”, “in other embodiments”, “in some other embodiments”, etc. that appear in various occasions herein do not necessarily refer to the same embodiment, but is meant to describe “one or more but not all embodiments”, unless otherwise specifically emphasized. The terms “including”, “comprising”, “having” and their variations all meant to describe “including but not limited to”, unless otherwise specifically emphasized.

The embodiments described herein are only used to illustrate the technical solutions of the present disclosure, rather than to limit the same. Although the present disclosure has been described in detail with reference to the aforementioned embodiments, those skilled in the art should understand that the technical solutions described in the aforementioned embodiments may still be modified, or some of the technical features may be replaced by other equivalents. Such modifications or replacements do not deviate the essence of the corresponding technical solutions from the spirit and scope of the technical solutions of the embodiments of the present application, and should all be included in the scope of the present disclosure.

What is claimed is:

1. A rotary switch for vehicle, comprising:
a bearing frame having a cylindrical structure, and the bearing frame is provided with an accommodation space and a plurality of elastic pressing units spaced apart along an axial direction of the bearing frame;
a circuit board module disposed in the accommodation space; the circuit board module is provided with a plurality of press switches spaced apart corresponding to the plurality of elastic press units; and
a pressing sleeve rotatably mounted on the bearing frame; the pressing sleeve is provided with a plurality of pressing protrusions corresponding to the plurality of elastic pressing units, and the plurality of pressing protrusions are arranged in a stepped manner along a circumferential direction of the bearing frame;
wherein, a pressing column of the elastic pressing units has an arc-shaped structure with one end facing the pressing switch being convex toward the pressing switch.

2. The rotary switch for vehicle of any one of claim 1, wherein the rotary switch for vehicle includes a rotating member; the rotating member is located at one end of the bearing frame and fixed to the pressing sleeve.

3. The rotary switch for vehicle of claim 1, wherein the elastic pressing unit includes a plurality of first elastic pressing units; the first elastic pressing unit is integrally formed to include a U-shaped portion, a bearing portion, a pushing protrusion and the pressing column; one end of the U-shaped portion is integrally connected to the bearing frame, and the other end of the U-shaped portion is connected to the bearing portion; the pushing protrusion is arranged on one side of the bearing portion corresponding to the pressing protrusion; the pressing column is arranged on the other side of the bearing portion and opposite to the pushing protrusion.

4. The rotary switch for vehicle of any one of claim 3, wherein the rotary switch for vehicle includes a rotating member; the rotating member is located at one end of the bearing frame and fixed to the pressing sleeve.

5. The rotary switch for vehicle of claim 3, wherein the elastic pressing unit includes at least one second elastic pressing unit; the second elastic pressing unit is integrally formed to include a cross bar, a C-shaped portion, the bearing portion, the pushing protrusion and the pressing column; both ends of the cross bar are integrally connected to the bearing frame; one end of the C-shaped portion is connected to the cross bar, and the other end of the C-shaped portion is connected to the bearing portion; the pushing protrusion is arranged on one side of the bearing portion corresponding to the pressing protrusion; the pressing column is arranged on the other side of the bearing portion and opposite to the pushing protrusion.

6. The rotary switch for vehicle of claim 5, wherein the second elastic pressing unit is adjacent to one end of the accommodation space and is located away from a rotating member of the rotary switch for vehicle.

7. The rotary switch for vehicle of claim 5, wherein the rotary switch for vehicle includes a rotating member; the rotating member is located at one end of the bearing frame and fixed to the pressing sleeve.

8. The rotary switch for vehicle of claim 7, wherein the bearing frame includes at least one elastic positioning portion; the elastic positioning portion is located at one end of the bearing frame and is adjacent to the rotating member; the rotating member includes a wave portion corresponding to the elastic positioning portion; the elastic positioning portion is embedded in one of the troughs of the wave portion.

9. The rotary switch for vehicle of claim 8, wherein the distance between the troughs of the wave portion corresponds to the distance between the plurality of elastic pressing units.

10. The rotary switch for vehicle of claim 1, wherein the rotary switch for vehicle includes an outer sleeve; the outer sleeve is sleeved on the outside of the pressing sleeve.

11. The rotary switch for vehicle of claim 3, wherein two of the first elastic pressing units form a group, and a reinforcing rib is provided between two of the first elastic pressing units in a group.
